(19) United States
(12) Patent Application Publication
(10) Pub. No.: US 2002/0137299 A1
(43) Pub. Date: Sep. 26, 2002

(54) Method for reducing the gate induced drain leakage current

(76) Inventors: Hua-Chou Tseng, Hsin-Chu City (TW); Tony Lin, Hsin-Chu City (TW)

Correspondence Address: POWELL, GOLDSTEIN, FRAZER & MURPHY LLP, 1001 Pennsylvania Ave, Suite 600 North, WASHINGTON, DC, 20004, US

(21) Appl. No.: 09/813,049

(22) Filed: Mar. 20, 2001

(51) Int. Cl. H01L 21/331

(52) U.S. Cl. 438/373

(57) ABSTRACT

The present invention provides a method to fabricate an MOS transistor and to reduce the gate-induced-drain-leakage current. The method is primarily to form a mask on the top of the gate. Because of the screening of the mask, spaced regions will be formed between the gate and the lightly doped drain/source regions in an ion-implantation process. Afterward, By using another ion-implantation process with opposite conductive type ions, package regions is then formed between the substrate and the lightly doped drain/source regions. Then, a sidewall of the gate is formed, and the drain/source regions are also formed by an ion-implantation process. Finally, an anneal process is performed to complete the fabrication of the MOS transistor. Because of the existence of the spaced regions that we propose in advance, such design can avoid overlap between a gate and lightly doped drain/source regions. Consequently, the method provided in the present invention can decrease the problem of gate-induced-drain-leakage current.

### BACKGROUND

1. Field of the Invention

The present invention generally relates to a method for manufacturing an MOS transistor, and in particular to a method for manufacturing an MOS transistor and reducing the gate-induced-drain-leakage current.

2. Description of the Prior Art

A prior method of manufacturing an MOS transistor generally comprises the followings: firstly, as shown in FIG. 1A, a polysilicon layer 102 is formed on a substrate 101. A photoresist layer 103 is then formed on the layer of polysilicon 102, and is patterned to define a gate. Secondly, an etching is performed to remove the extra part of the polysilicon layer 102, as shown in FIG. 1B, so that a gate 104 is formed. Then, an ion implantation, such as N-type ion implantation, is performed to form lightly doped drain/source regions 105, as shown in FIG. 1C, and it should be mentioned that the incident direction of ions is parallel to the normal of the surface of said substrate 101, so that the lightly doped drain/source regions 105 are alongside the gate. Afterward, an oblique ion implantation in which ions are with opposite conductive type, such as P-type ions, is performed to form pocket regions 106, as shown in FIG. 1D. It should be noted that the incident direction of ions is tilted by an angle from the normal of a surface of the substrate 101 and the ions are implanted more deeper than the lightly doped drain/source regions are. Therefore, the pocket regions 106 is positioned between the lightly doped drain/source regions 105 and the substrate 101. Then, a dielectric layer is deposited to cover the gate 104, lightly doped drain/source regions 105, and the substrate 101. The dielectric layer is then etched to form a sidewall 107 of the gate 104, as shown in FIG. 1E. Afterwards, another ion-implantation, such as an N-type ion-implantation, is performed to form drain/source regions 108 by use of the gate 104 and the sidewall 107 as a mask, as shown in FIG. 1F. Finally, an anneal process is performed so that the fabrication of an MOS transistor is completed. But the anneal process will cause a phenomenon of diffusion, so that overlap region 109 will occur between the gate 104 and the drain/source regions 105. This overlap region 109 will cause a gate-induced-drain-leakage current, so that the performance of the device will degrade. In order to avoid those drawbacks, the overlap region 109 should be eliminated.

### SUMMARY

It is an object of the invention to provide a method for forming an MOS transistor.

It is another object of the invention to provide a method to reduce overlap region between gate and lightly doped drain/source regions, so that the gate-induced-drain-leakage current can also be reduced.

According to the foregoing objects, the present invention provides a method comprising the following steps: firstly, a polysilicon layer is deposited on a substrate. Afterward, a dielectric layer is deposited on the polysilicon layer. A photoresist layer is then deposited on the dielectric layer, and is patterned to define a mask. Then, a part of the dielectric layer is removed by an etching step, and the remaining part of the dielectric layer is used as a mask. Afterward, the photoresist layer is removed. By using an etching process, parts of the polysilicon layer are removed to form a gate. It should be mentioned that the etching for forming the gate is an overetching, so that the width of an end of the gate which contacts to the substrate is smaller than the width of the mask. Afterward, an ion-implantation is performed to form lightly doped drain/source regions. Because of the screening of the mask, the width of the channel between the lightly doped drain and lightly doped source is about equal to that of the mask and a spaced region is existed between the gate and the lightly doped drain/source regions. Then, ions with opposite conductive type to the lightly doped drain/source regions are implanted to form pocket regions. The incident direction of the implanted ions is tilted with an angle to the normal of the surface of the substrate. And the ions are implanted into a certain region so that the pocket regions is located between the substrate and the lightly doped drain/source regions. Afterward, an oxide layer is deposited to cover the mask, the gate, the lightly doped drain/source regions, and the substrate, and this layer is then etched to form a sidewall of the gate. Then, by using of the gate and the sidewall as a mask, another ion-implantation is performed to form drain/source regions. Finally, an anneal process is performed to complete the fabrication of an MOS transistor. Because of the existence of spaced regions that we propose in advance, such design can avoid overlaps between a gate and lightly doped drain/source regions. Consequently, the method provided in the present invention can decrease the problem of gate-induced-drain-leakage current.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A through FIG. 1G provide cross-sectional views at various stages in an prior method for forming an MOS transistor.

FIG. 2A through FIG. 21 provide cross-sectional views at various stages in an embodiment for forming an MOS transistor.

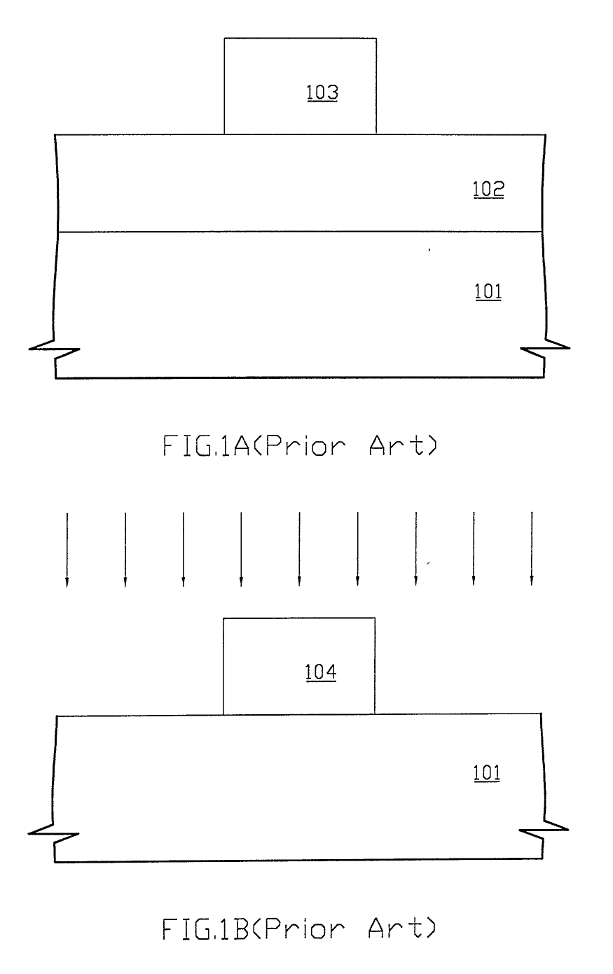

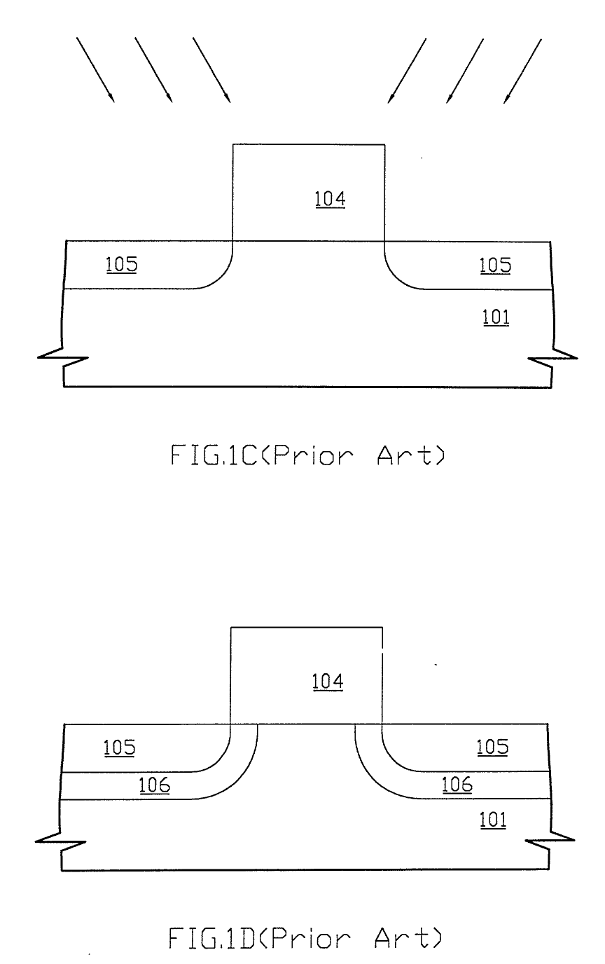

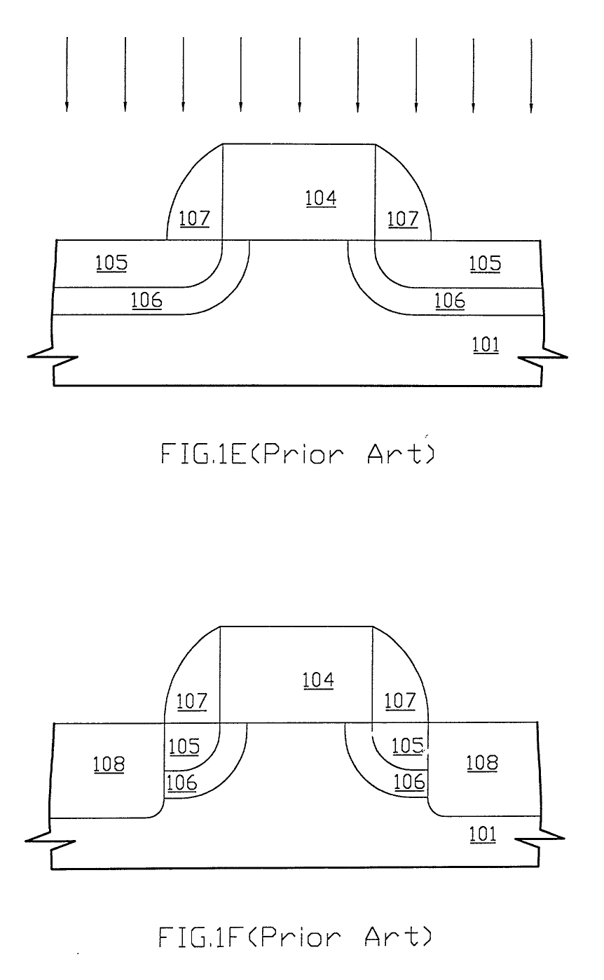

### DESCRIPTION OF THE PREFERRED EMBODIMENT

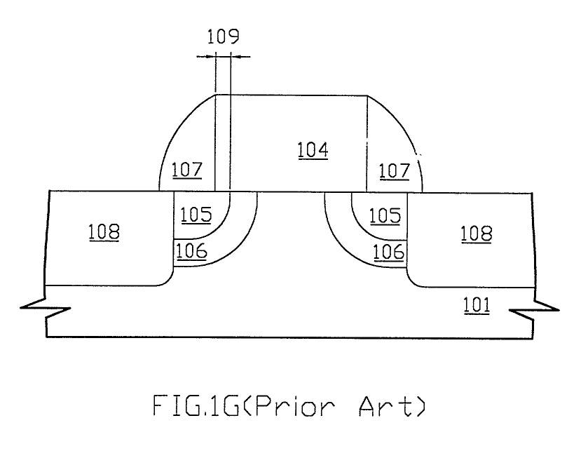

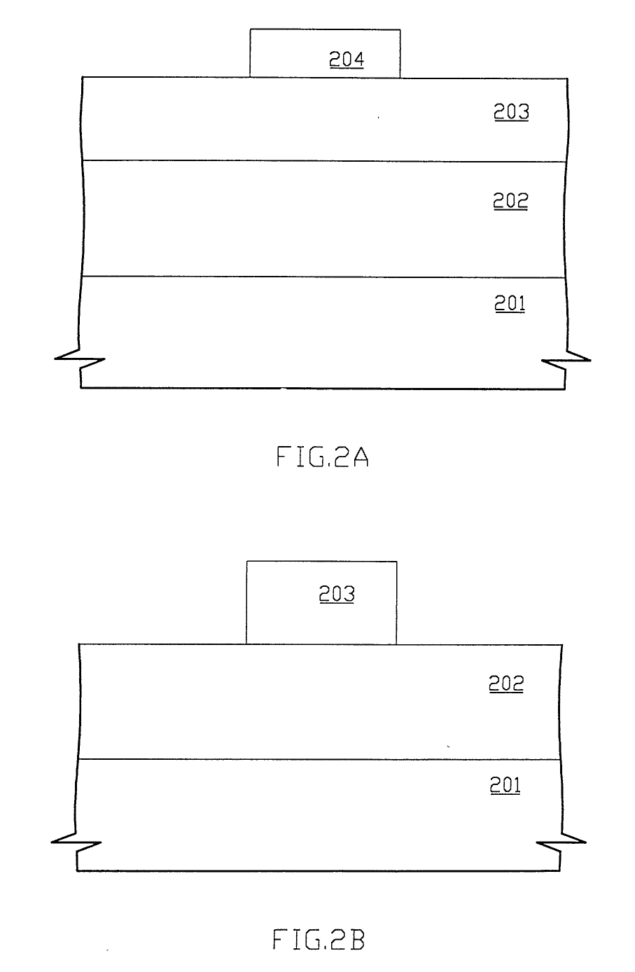

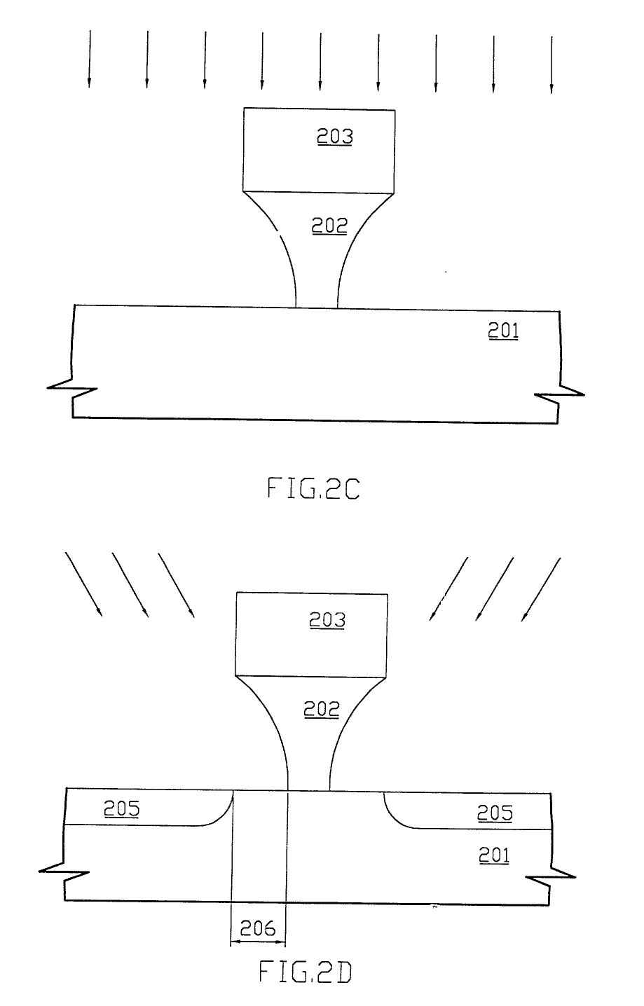

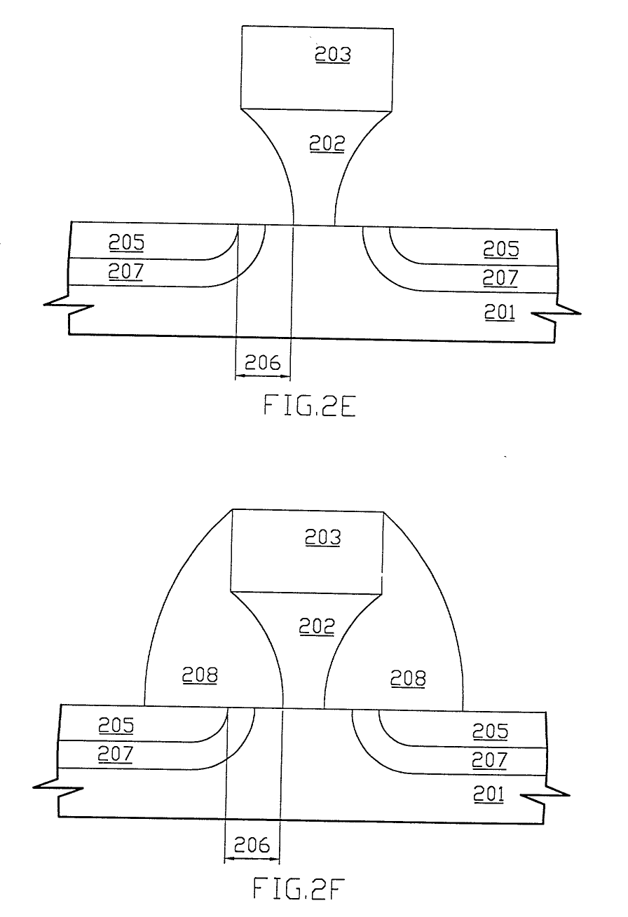

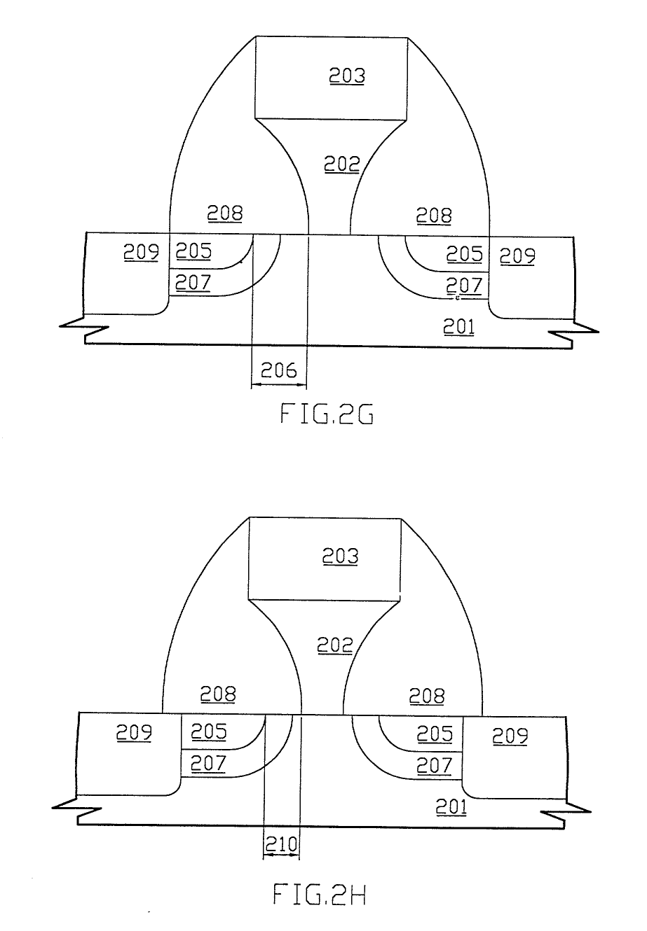

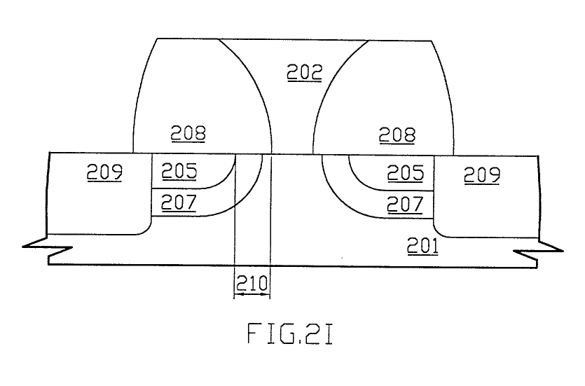

An embodiment of this invention comprises the following steps: firstly, as shown in FIG. 2A, a substrate 201 is provided, and a polysilicon layer 202 is deposited on the surface of the substrate 201. Secondly, a dielectric layer 203 is deposited on the polysilicon layer 202, and the material of the dielectric layer can be silicon oxide, silicon nitride, or silicon oxynitride. A photoresist 204 is deposited on the dielectric layer 203, and then is patterned to define a mask. Afterward, an etching is performed to remove a part of the dielectric layer 203, and the residue of the dielectric layer 203 is to act as a mask, as shown in FIG. 2B. Subsequently, the photoresist 204 is removed. Another etching, such as a plasma etching, is then performed to remove a part of the polysilicon layer, so that a gate 202 is formed. It should be mentioned that the etching for forming the gate 202 is an overetching, so that the width of an end of the gate 202 which contacts to the substrate 201 is smaller than the width of the mask 203, as shown in FIG. 2C. Afterward, an ion-implantation, such as an N-type ion-implantation, is performed to form lightly doped drain/source regions 205. The incident direction of the implanted ion is parallel to the normal of the surface of the substrate 201, so that the lightly doped drain/source regions are formed in the upper part of the substrate and are alongside the gate. And the width of the channel between the lightly doped drain and lightly doped source is about equal to that of the mask 203. As shown in FIG. 2D, It should be noted that there is a spaced region 206 between the gate 202 and the lightly doped drain/source regions 205. Then, ions with opposite conductive type to the lightly doped drain/source regions 205, such as P-type ions, are then implanted to form pocket regions 207, as shown in FIG. 2E. The incident direction of the implanted ions is tilted with an angle to the normal of the surface of the substrate 201. And the ions are implanted into a certain region so that the pocket regions 207 is located between the substrate 201 and the lightly doped drain/source regions 205. Afterward, an oxide layer is deposited to cover the mask 203, the gate 202, the lightly doped drain/source regions 205, and the substrate 201, and this layer is then etched to form a sidewall 208 of the gate 202, as shown in FIG. 2F. Then, by using of the gate 202 and the sidewall 208 as a mask, another ion-implantation, such as an N-type ion-implantation, is performed to form drain/source regions 209, as shown in FIG. 2G. Finally, an anneal process is performed to complete the fabrication of an MOS transistor. Because of a diffusion of the implanted ions caused by the anneal process, the length of the channel between the lightly doped drain and the lightly doped source will be reduced, in other words, the lightly doped drain/source 205 will be closer to the gate 202, as shown in FIG. 2H. But a smaller spaced regions 210 is still existed between the gate 202 and the lightly doped drain/source regions 205, which is due to the existence of the spaced regions 206 that we propose in advance. Such design can avoid an overlap between a gate and lightly doped drain/source regions. Consequently, the method provided in the present invention can decrease the problem of gate-induced-drain-leakage current.

Furthermore, a chemical mechanical polishing (CMP) process or an etching step can be performed to remove a part of the dielectric layer over the gate 202, as shown in FIG. 2I. In addition, a gate oxide layer (not shown) may be deposited between the gate 202 and the substrate 201. It should be mentioned that the method described here includes many process steps well known in the art like deposition, etching and ion-implantation which are not particularly limited and not discussed in detail.

Although specific embodiments have been illustrated and described, it will be obvious to those skilled in the art that various modifications may be made without departing from what is intended to be limited solely by the appended claims.

What is claimed is:

1. A method for reducing overlap regions between an gate and ion-implanting regions, said method comprising the steps of:
providing a substrate;
forming a polysilicon layer on said substrate;
forming a dielectric layer on said polysilicon layer;
removing parts of said dielectric layer, and then a remaining part of said dielectric layer is used as a mask;
etching said polysilicon layer to form a gate, wherein one end of said gate is connected to said substrate, and the width of said end of said gate is smaller than the width of said mask;
performing a first ion-implantation with first conductive type ions to form a first ion-implanting region at one side of said gate, and to form a second ion-implanting region at the opposite side of said gate, wherein a channel region is existed between said first ion-implanting region and said second ion-implanting region, and the width of said channel region is about equal to the width of said mask;
performing a second ion-implantation with second conductive type ions to form pocket regions between said first ion-implanting region and said substrate as well as between said second ion-implanting region and said substrate, wherein the conductive type of said second conductive type ions is opposite to that of said first conductive type ions, and the incident direction of said second conductive type ions is tilted with an angle to the normal of a surface of said substrate.

2. The method according to claim 1, wherein said first ion-implanting region is a lightly doped drain, and said second ion-implanting region is a lightly doped source.

3. The method according to claim 1, wherein said first conductive type ions are N-type ions, and said second conductive type ions is P-type ions.

4. The method according to claim 1, wherein said first conductive type ions are P-type ions, and said second conductive type ions is N-type ions.

5. The method according to claim 1, wherein the material of said dielectric layer comprises silicon nitride.

6. The method according to claim 1, wherein the material of said dielectric layer comprises silicon oxynitride.

7. The method according to claim 1, wherein said angle is greater than 0 degree.

8. The method according to claim 1, further comprising a gate layer deposited between said polysilicon layer and said substrate.

9. A method for fabricating an MOS transistor, said method comprising the steps of:
providing a substrate;
forming a polysilicon layer on said substrate;
forming a first dielectric layer on said polysilicon layer;
removing parts of said first dielectric layer, and then a remaining part of said first dielectric layer is used as a mask;
etching said polysilicon layer to form a gate, wherein one end of said gate is connected to said substrate, and the width of said end of said gate is smaller than the width of said mask;
performing a first ion-implantation with first conductive type ions to form a lightly doped drain region at one side of said gate, and to form a lightly doped source region at the opposite side of said gate, wherein a channel region is existed between said lightly doped drain region and said lightly doped source region, and the width of said channel region is about equal to the width of said mask;
performing a second ion-implantation with second conductive type ions to form pocket regions between said lightly doped drain region and said substrate as well as between said lightly doped source region and said substrate, wherein the conductive type of said second conductive type ions is opposite to that of said first conductive type ions, and the incident direction of said second conductive type ions is tilted with an angle to the normal of a surface of said substrate;
depositing a second dielectric layer to cover said substrate, said lightly doped drain region, said lightly doped source region, said gate, and said mask;
performing an etching to remove parts of said second dielectric layer, so that a sidewall of said gate is formed;
performing a third ion-implantation with said first conductive type ions to form a drain and a source;
performing an anneal process.

10. The method according to claim 9, wherein said first conductive type ions are N-type ions, and said second conductive type ions is P-type ions.

11. The method according to claim 9, wherein said first conductive type ions are P-type ions, and said second conductive type ions is N-type ions.

12. The method according to claim 9, wherein the material of said first dielectric layer comprises silicon nitride.

13. The method according to claim 9, wherein the material of said first dielectric layer comprises silicon oxynitride.

14. The method according to claim 9, wherein said second dielectric layer comprises silicon oxide.

15. The method according to claim 9, wherein said angle is greater than 0 degree.

16. The method according to claim 9, further comprising a gate layer deposited between said polysilicon layer and said substrate.
